(19) United States
(12) Patent Application Publication
(10) Pub. No.: US 2015/0054007 A1
(43) Pub. Date: Feb. 26, 2015

(54) Food Lighting Device and Meat Lighting Device

(71) Applicant: Funai Electric Co., Ltd., Osaka (JP)

(72) Inventor: Keiichi EDAKA, Daito-shi (JP)

(21) Appl. No.: 14/445,308

(22) Filed: Jul. 29, 2014

(30) Foreign Application Priority Data
Aug. 20, 2013 (JP) 2013-170437

(51) Int. Cl. H01L 33/50; H01L 33/52; A47F 11/10; H01L 27/15

(52) U.S. Cl. CPC H01L 33/507; H01L 27/15; H01L 33/52; A47F 11/10
USPC 257/89

(57) ABSTRACT

In a food lighting device, a blue LED element, a green phosphor, and a red LED element or a red phosphor are selected such that light synthesized by the blue LED element, the green phosphor, and the red LED element or the red phosphor becomes white light whose wavelength component in the vicinity of 580 nm or in the vicinity of 600 nm is reduced.

### BACKGROUND OF THE INVENTION

1. Field of the Invention

The present invention relates to a food lighting device and a meat lighting device, and more particularly, it relates to a food lighting device and a meat lighting device each including a phosphor absorbing light and converting the light into long-wavelength light.

2. Description of the Background Art

A food lighting device or the like including a phosphor absorbing light and converting the light into long-wavelength light is known in general, as disclosed in Japanese Patent Laying-Open No. 62-234862 (1987).

Japanese Patent Laying-Open No. 62-234862 discloses a fluorescent lamp (food lighting device) including a glass bulb, a luminous layer formed on the inner surface of the glass bulb, and a non-luminous layer formed between the glass bulb and the luminous layer, having ultraviolet absorption. This fluorescent lamp is particularly employed for display lighting of food (seafood, meat, and so on). In this fluorescent lamp, the luminous layer is formed of a narrow-band emission phosphor and a blue-green phosphor and a deep red phosphor both excited by blue light.

When the fluorescent lamp described in Japanese Patent Laying-Open No. 62-234862 is employed, however, food is oxidized by heat transferred from a fluorescent lamp body, and hence the freshness is lowered quickly.

When a lighting device employing an LED element is applied for display lighting of food, on the other hand, light of a wavelength causing a sense of spoilage of food (conveying the impression of lowering of the freshness) may be contained since the emission spectrum is different from that of the conventional food lighting device such as the fluorescent lamp. In this case, the light of the lighting device disadvantageously causes a sense of spoilage of food.

### SUMMARY OF THE INVENTION

The present invention has been proposed in order to solve the aforementioned problem, and an object of the present invention is to provide a food lighting device and a meat lighting device each capable of suppressing generation of a sense of spoilage of food by illumination light while suppressing a deterioration of the freshness of food resulting from heat.

A food lighting device according to a first aspect of the present invention includes a blue LED element emitting light having a blue wavelength, a green phosphor having an emission peak wavelength of not more than 560 nm and an emission spectrum with a half width of not more than 80 nm, and a red LED element or a red phosphor emitting red light having an emission peak wavelength of at least 620 nm and less than 680 nm and an emission spectrum with a half width of not more than 40 nm, while the blue LED element, the green phosphor, and the red LED element or the red phosphor are selected such that light synthesized by the blue LED element, the green phosphor, and the red LED element or the red phosphor becomes white light whose wavelength component in the vicinity of 580 nm or in the vicinity of 600 nm is reduced.

In the food lighting device according to the first aspect of the present invention, as hereinabove described, the blue LED element, the green phosphor, and the red LED element or the red phosphor are selected such that the light synthesized by the blue LED element, the green phosphor, and the red LED element or the red phosphor becomes the white light whose wavelength component in the vicinity of 580 nm or in the vicinity of 600 nm is reduced, whereby a deterioration of the freshness of food resulting from heat can be suppressed. Furthermore, inclusion of the wavelength component in the vicinity of 600 nm causing a sense of spoilage of food in the synthesized light can be suppressed, and hence generation of a sense of spoilage of food by illumination light can be suppressed. Consequently, the intrinsic freshness of food can be effectively exhibited. When white light whose wavelength component in the vicinity of 580 nm is reduced is obtained, the luminous efficiency of the red LED element can be improved by employing the red LED element having the emission peak wavelength on the shorter wavelength side (in the vicinity of 620 nm), and hence the power consumption of the food lighting device can be reduced.

In the aforementioned food lighting device according to the first aspect, the emission spectrum of the light synthesized by the blue LED element, the green phosphor, and the red LED element or the red phosphor is preferably configured such that the intensity of the wavelength component in the vicinity of 580 nm or in the vicinity of 600 nm is relatively small as compared with the intensity of the emission peak wavelength of the green phosphor. According to this structure, the intensity of the wavelength component in the vicinity of 580 nm or in the vicinity of 600 nm causing a sense of spoilage of food is relatively small, and hence the generation of a sense of spoilage of food by the illumination light can be suppressed.

In the aforementioned food lighting device according to the first aspect, the red light having the emission peak wavelength of at least 620 nm and less than 680 nm and the emission spectrum with the half width of not more than 40 nm is preferably emitted by the red LED element, and the blue LED element, the green phosphor, and the red LED element are preferably selected such that light synthesized by the blue LED element, the green phosphor, and the red LED element becomes the white light whose wavelength component in the vicinity of 580 nm or in the vicinity of 600 nm is reduced. According to this structure, the emission spectrum hardly has a broad band, and hence inclusion of the wavelength component in the vicinity of 600 nm causing a sense of spoilage of food can be easily suppressed even in the case where the emission peak wavelength of the red light is located on the short wavelength side close to 600 nm. Consequently, the intrinsic freshness of food can be effectively exhibited.

In this case, the food lighting device preferably further includes a dam material provided to surround the blue LED element and the red LED element and transparent sealing resins configured to seal the blue LED element and the red LED element, and the green phosphor is preferably dispersed in the transparent sealing resin sealing the blue LED element. According to this structure, the green phosphor can be easily excited by blue light emitted from the blue LED element.

In the aforementioned food lighting device including the transparent sealing resins configured to seal the blue LED element and the red LED element, the transparent sealing resin configured to seal the red LED element is preferably provided separately from the transparent sealing resin sealing the blue LED element, in which the green phosphor is dispersed. According to this structure, an influence of the green phosphor on the red light emitted from the red LED element can be suppressed.

In the aforementioned food lighting device according to the first aspect, the color temperature of the light synthesized by the blue LED element, the green phosphor, and the red LED element or the red phosphor is preferably less than 8000 K. According to this structure, a difference in color temperature between light of a ceiling lighting device or the like in a sales store generally having a color temperature of less than 7000 K and light of the food lighting device can be reduced, and hence the light of the food lighting device and the light of the ceiling lighting device or the like in the sales store can be blended with each other. Thus, a feeling of strangeness provided for a consumer due to the difference in color temperature can be suppressed.

In this case, the color temperature of the light synthesized by the blue LED element, the green phosphor, and the red LED element or the red phosphor is preferably less than 7000 K. According to this structure, the difference in color temperature between the light of the ceiling lighting device or the like in the sales store generally having the color temperature of less than 7000 K and the light of the food lighting device can be further reduced, and hence a feeling of strangeness provided for the consumer due to the difference in color temperature can be further suppressed.

In the aforementioned food lighting device according to the first aspect, in the green phosphor, light excited by blue light emitted from the blue LED element preferably has an emission peak wavelength of not more than 560 nm and an emission spectrum with a half width of not more than 80 nm, and in the red phosphor, the light excited by the blue light emitted from the blue LED element preferably has an emission peak wavelength of at least 620 nm and less than 680 nm and an emission spectrum with a half width of not more than 40 nm. According to this structure, the blue LED element can be used as a light source, and hence the deterioration of the freshness of food resulting from heat can be easily suppressed as compared with the case where a fluorescent lamp or the like is used as a light source.

In this case, the food lighting device preferably further includes a dam material provided to surround the blue LED element and a transparent sealing resin configured to seal the blue LED element, and the green phosphor and the red phosphor are preferably dispersed in the transparent sealing resin sealing the blue LED element. According to this structure, white light can be synthesized while the number of LED elements (one blue LED element) is reduced.

In the aforementioned food lighting device in which the green phosphor and the red phosphor are dispersed in the sealing resin sealing the blue LED element, the green phosphor and the red phosphor are preferably dispersed in the transparent sealing resin that is single. According to this structure, the structure of the food lighting device can be simplified, unlike the case where the green phosphor and the red phosphor are dispersed in separate sealing resins.

In the aforementioned food lighting device in which the green phosphor and the red phosphor are dispersed in the sealing resin sealing the blue LED element, the transparent sealing resin preferably includes a sealing resin in which the green phosphor is dispersed and a sealing resin provided separately from the sealing resin in which the green phosphor is dispersed, in which the red phosphor is dispersed. According to this structure, adjustment of the amount of dispersion of the green phosphor and adjustment of the amount of dispersion of the red phosphor can be performed separately.

In the aforementioned food lighting device according to the first aspect, the green phosphor preferably includes one selected from β-sialon or (Ba,Sr)₂SiO₄:Eu. According to this structure, the green phosphor having the narrow emission spectrum with the half width of not more than 80 nm can be obtained, and hence inclusion of the wavelength component in the vicinity of 600 nm causing a sense of spoilage of food due to light of a green wavelength can be suppressed.

In the aforementioned food lighting device according to the first aspect, the red phosphor preferably includes a complex fluoride phosphor. According to this structure, the red phosphor having the emission spectrum with the half width of not more than 40 nm can be obtained, and hence inclusion of the wavelength component in the vicinity of 600 nm causing a sense of spoilage of food due to light of a red wavelength can be suppressed.

The aforementioned food lighting device according to the first aspect is preferably employed for illumination of meat, and the blue LED element, the green phosphor, and the red LED element or the red phosphor are preferably selected such that the light synthesized by the blue LED element, the green phosphor, and the red LED element or the red phosphor becomes white light whose wavelength component in the vicinity of 600 nm is reduced. According to this structure, inclusion of the wavelength component in the vicinity of 600 nm making fat on meat to appear yellow (causing a sense of spoilage) in the synthesized light can be suppressed, and hence the fat on meat can be made to appear whiter, so that generation of a sense of spoilage of meat by the illumination light can be suppressed.

In this case, the blue LED element preferably has an emission peak wavelength in the range of at least 420 nm to less than 480 nm. According to this structure, the green phosphor having the emission peak wavelength of not more than 560 nm and the emission spectrum with the half width of not more than 80 nm and the red LED element or the red phosphor emitting the red light having the emission peak wavelength of at least 620 nm and less than 680 nm and the emission spectrum with the half width of not more than 40 nm can synthesize the white light whose wavelength component in the vicinity of 600 nm is reduced.

In the aforementioned food lighting device employed for illumination of meat, the intensity of the wavelength component in the vicinity of 600 nm is preferably not more than 80% of the intensity of the emission peak wavelength of the green phosphor. According to this structure, the intensity of the wavelength component in the vicinity of 600 nm causing a sense of spoilage of food is reliably reduced, and hence the generation of a sense of spoilage of food by the illumination light can be reliably suppressed.

The aforementioned food lighting device according to the first aspect is preferably employed for illumination of fresh fish, and the blue LED element, the green phosphor, and the red LED element or the red phosphor are preferably selected such that the light synthesized by the blue LED element, the green phosphor, the red LED element or the red phosphor becomes white light whose wavelength component in the vicinity of 580 nm is reduced. According to this structure, the red LED element or the red phosphor having the emission peak wavelength on the shorter wavelength side (in the vicinity of 620 nm) can be easily employed. Furthermore, when the red LED element is employed, the luminous efficiency of the red LED element can be improved, and hence the power consumption of the food lighting device can be reduced.

In this case, the blue LED element preferably has an emission peak wavelength in the vicinity of 450 nm, the green phosphor preferably includes β-sialon having an emission peak wavelength in the vicinity of 545 nm and a half width of 54 nm, and the red LED element preferably has an emission peak wavelength in the vicinity of 625 nm. According to this structure, the white light whose wavelength component in the vicinity of 580 nm is reduced can be easily synthesized.

In the aforementioned food lighting device employed for illumination of fresh fish, the intensity of the wavelength component in the vicinity of 580 nm is preferably not more than 80% of the intensity of the emission peak wavelength of the green phosphor. According to this structure, the intensity of the wavelength component in the vicinity of 580 nm causing a sense of spoilage of food is reliably reduced, and hence the generation of a sense of spoilage of food by the illumination light can be reliably suppressed.

A meat lighting device according to a second aspect of the present invention includes a blue LED element emitting light having a blue wavelength, a green phosphor having an emission peak wavelength of not more than 560 nm and an emission spectrum with a half width of not more than 80 nm, and a red LED element or a red phosphor emitting red light having an emission peak wavelength of at least 620 nm and less than 680 nm and an emission spectrum with a half width of not more than 40 nm, while the blue LED element, the green phosphor, and the red LED element or the red phosphor are selected such that light synthesized by the blue LED element, the green phosphor, and the red LED element or the red phosphor becomes white light whose wavelength component in the vicinity of 600 nm is reduced.

In the meat lighting device according to a second aspect of the present invention, as hereinabove described, the blue LED element, the green phosphor, and the red LED element or the red phosphor are selected such that the light synthesized by the blue LED element, the green phosphor, and the red LED element or the red phosphor becomes the white light whose wavelength component in the vicinity of 600 nm is reduced, whereby a deterioration of the freshness of meat resulting from heat can be suppressed. Furthermore, inclusion of the wavelength component in the vicinity of 600 nm causing a sense of spoilage of meat in the synthesized light can be suppressed, and hence generation of a sense of spoilage of meat by illumination light can be suppressed. Consequently, the intrinsic freshness of food (meat) can be effectively exhibited.

According to the present invention, as hereinabove described, the food lighting device and the meat lighting device each capable of suppressing the generation of a sense of spoilage of food by the illumination light while suppressing the deterioration of the freshness of food resulting from heat can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view for illustrating a meat or fresh fish LED lighting device according to a first or second embodiment of the present invention;

FIG. 2 is a schematic view for illustrating a meat LED lighting device according to a third embodiment of the present invention;

FIG. 3 is a diagram showing the emission spectrum of a meat LED lighting device according to Example 1 of the present invention;

FIG. 4 is a diagram showing the emission spectrum of a fresh fish LED lighting device according to Example 2 of the present invention;

FIG. 5 is a diagram showing the emission spectrum of a meat LED lighting device according to a comparative example of the present invention; and

FIG. 6 is a schematic view for illustrating an LED lighting device according to a modification of the third embodiment of the present invention.

### DESCRIPTION OF THE PREFERRED EMBODIMENTS

Embodiments of the present invention are hereinafter described with reference to the drawings.

### First Embodiment

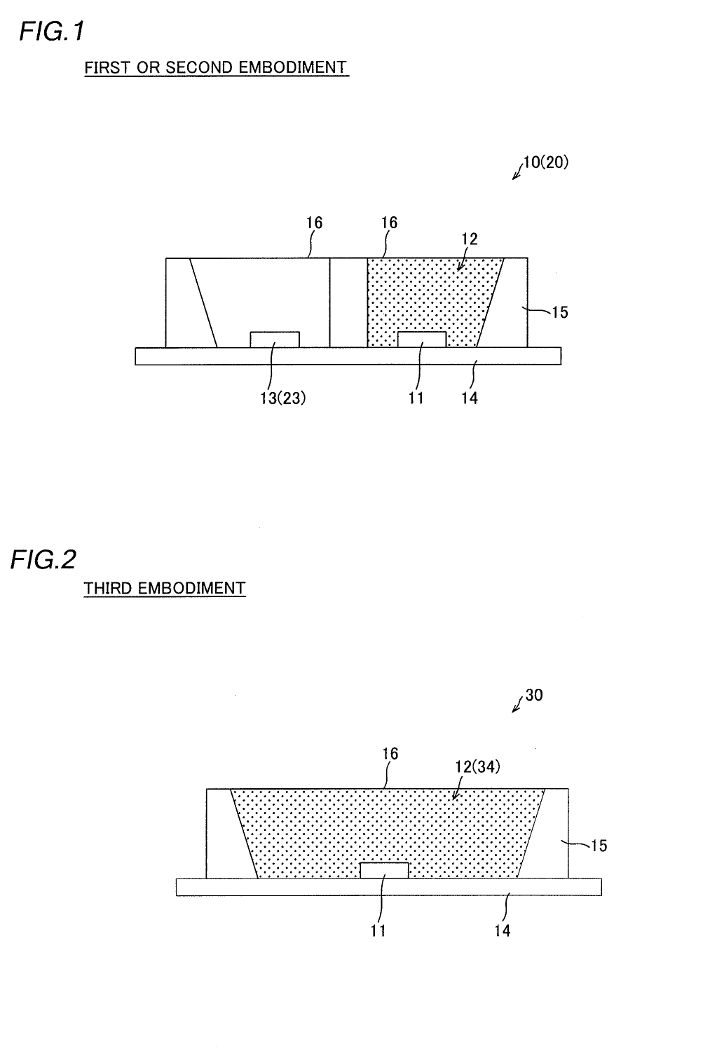

The structure of a meat LED lighting device 10 according to a first embodiment of the present invention is now described with reference to FIG. 1. The meat LED lighting device 10 is an example of the “food lighting device” in the present invention.

The meat LED lighting device 10 according to the first embodiment of the present invention includes a blue LED element 11 emitting light having a blue wavelength, a green phosphor 12 (shown by hatching) absorbing the light of a blue wavelength emitted from the blue LED element 11 and emitting light having a green wavelength, and a red LED element 13 emitting light having a red wavelength, as shown in FIG. 1. The meat LED lighting device 10 further includes an LED substrate 14 mounted with the blue LED element 11 and the red LED element 13, a dam material 15 provided to surround the blue LED element 11 and the red LED element 13, and transparent sealing resins 16 for sealing the blue LED element 11 and the red LED element 13. The meat LED lighting device 10 is configured such that the green phosphor 12 is dispersed in the sealing resin 16 sealing the blue LED element 11. The meat LED lighting device 10 is configured such that light synthesized by the blue LED element 11, the green phosphor 12, and the red LED element 13 becomes white light.

The sealing resins 16 are made of transmissive resin such as silicone resin, epoxy resin, acrylic resin, or polycarbonate resin. In the sealing resin 16, a granulous diffusion material made of an inorganic material such as aluminum oxide or silica or an organic material such as fluorinated resin as needed in addition to the green phosphor 12 may be dispersed.

The blue LED element 11 has an emission peak wavelength in the range of at least 420 nm to less than 480 nm. The blue LED element 11 more preferably has an emission peak wavelength in the vicinity of 450 nm.

In the green phosphor 12, light excited by blue light has an emission peak wavelength of not more than 560 nm and has an emission spectrum with a half width of not more than 80 nm. The green phosphor 12 is made of one or a combination of two selected from β-sialon or (Ba,Sr)₂SiO₄:Eu. When β-sialon is employed as the green phosphor, β-sialon having an emission peak wavelength in the range of at least 520 nm to not more than 560 nm and a half width in the range of at least 50 nm to not more than 80 nm can be employed.

The red LED element 13 has an emission peak wavelength of at least 620 nm and less than 680 nm and an emission spectrum with a half width of not more than 40 nm. When the LED lighting device 10 is employed for meat, the red LED element 13 preferably has an emission peak wavelength on the higher wavelength side.

The meat LED lighting device 10 is configured to reduce a wavelength component in the vicinity of 600 nm of the emission spectrum of white light synthesized by the blue LED element 11, the green phosphor 12, and the red LED element 13. Specifically, the meat LED lighting device 10 is configured to be capable of suppressing expansion of the base of the emission spectrum of each of the green phosphor 12 and the red LED element 13 to the vicinity of 600 nm by selecting the green phosphor 12 having a half width of not more than 80 nm and the red LED element 13 having a half width of not more than 40 nm. Reducing the wavelength component in the vicinity of 600 nm means a state at an intensity relatively lower than the intensity of the emission peak wavelength of the emission spectrum of the green phosphor 12. The intensity of the wavelength component in the vicinity of 600 nm is preferably not more than 80% of the intensity of the emission peak wavelength of the green phosphor 12. The intensity of the wavelength component in the vicinity of 600 nm is more preferably not more than 50% of the intensity of the emission peak wavelength of the green phosphor 12. The intensity of the wavelength component in the vicinity of 600 nm is still more preferably not more than 25% of the intensity of the emission peak wavelength of the green phosphor 12.

The meat LED lighting device 10 is configured such that the white light synthesized by the blue LED element 11, the green phosphor 12, and the red LED element 13 has a color temperature of less than 8000 K. In the meat LED lighting device 10, the white light more preferably has a color temperature of less than 7000 K. The meat LED lighting device 10 is still preferably selected arbitrarily according to the color temperature of a lighting device set in a sales store or the like. Specifically, the color temperature of the meat LED lighting device 10 may be selected arbitrarily according to a “light bulb color (color temperature of about 3000 K)”, a “warm white color (color temperature of about 3500 K)”, a “white color (color temperature of about 4000 K)”, a “natural white color (color temperature of about 5000 K)”, a “daylight color (color temperature of about 6500 K)”, or the like used for the lighting device or the like commonly set in the sales store or the like.

With respect to the color temperature, a measurement value measured by a measurement method complying with JIS Z 8725 can be employed.

According to the first embodiment, the following effects can be obtained.

According to the first embodiment, as hereinabove described, the blue LED element 11, the green phosphor 12, and the red LED element 13 are selected such that the light synthesized by the blue LED element 11, the green phosphor 12, and the red LED element 13 becomes the white light whose wavelength component in the vicinity of 600 nm is reduced, whereby a deterioration of the freshness of food resulting from heat can be suppressed. Furthermore, inclusion of the wavelength component in the vicinity of 600 nm causing a sense of spoilage of food in the synthesized light can be suppressed, and hence generation of a sense of spoilage of food by illumination light of the meat LED lighting device 10 can be suppressed. Consequently, the intrinsic freshness of food can be effectively exhibited, and hence the freshness of food can be emphasized to a consumer, and consumer's motivation for purchase can be promoted.

According to the first embodiment, as hereinabove described, the emission spectrum of the light synthesized by the blue LED element 11, the green phosphor 12, and the red LED element 13 is configured such that the intensity of the wavelength component in the vicinity of 600 nm is relatively small as compared with the intensity of the emission peak wavelength of the green phosphor. Thus, the intensity of the wavelength component in the vicinity of 600 nm causing a sense of spoilage of food is relatively small, and hence the generation of a sense of spoilage of food by the illumination light can be suppressed.

According to the first embodiment, as hereinabove described, the red LED element 13 emits red light having the emission peak wavelength of at least 620 nm and less than 680 nm and the emission spectrum with the half width of not more than 40 nm, and the blue LED element 11, the green phosphor 12, and the red LED element 13 are selected such that the light synthesized by the blue LED element 11, the green phosphor 12, and the red LED element 13 becomes the white light whose wavelength component in the vicinity of 600 nm is reduced. Thus, the emission spectrum hardly has a broad band, and hence inclusion of the wavelength component in the vicinity of 600 nm causing a sense of spoilage of food can be easily suppressed even in the case where the emission peak wavelength of the red light is located on the short wavelength side close to 600 nm. Consequently, the intrinsic freshness of food can be effectively exhibited.

According to the first embodiment, as hereinabove described, the dam material 15 provided to surround the blue LED element 11 and the red LED element 13 and the transparent sealing resins 16 configured to seal the blue LED element 11 and the red LED element 13 are provided. Furthermore, the green phosphor 12 is dispersed in the sealing resin 16 sealing the blue LED element 11. Thus, the green phosphor 12 can be easily excited by blue light emitted from the blue LED element 11.

According to the first embodiment, as hereinabove described, the transparent sealing resin 16 configured to seal the red LED element 13 is provided separately from the sealing resin 16 sealing the blue LED element 11, in which the green phosphor 12 is dispersed. Thus, an influence of the green phosphor 12 on the red light emitted from the red LED element 13 can be suppressed.

According to the first embodiment, as hereinabove described, the color temperature of the light synthesized by the blue LED element 11, the green phosphor 12, and the red LED element 13 is less than 8000 K. According to this structure, a difference in color temperature between light of a ceiling lighting device or the like in the sales store generally having a color temperature of less than 7000 K and the light of the meat LED lighting device 10 can be reduced, and hence the light of the meat LED lighting device 10 and the light of the ceiling lighting device or the like in the sales store can be blended with each other. Thus, a feeling of strangeness provided for the consumer due to the difference in color temperature can be suppressed.

According to the first embodiment, as hereinabove described, the color temperature of the light synthesized by the blue LED element 11, the green phosphor 12, and the red LED element 13 is less than 7000 K. Thus, the difference in color temperature between the light of the ceiling lighting device or the like in the sales store generally having the color temperature of less than 7000 K and the light of the meat LED lighting device 10 can be further reduced, and hence a feeling of strangeness provided for the consumer due to the difference in color temperature can be further suppressed.

According to the first embodiment, as hereinabove described, in the green phosphor 12, the light excited by the blue light emitted from the blue LED element 11 has the emission peak wavelength of not more than 560 nm and the emission spectrum with the half width of not more than 80 nm. Thus, the blue LED element 11 and the red LED element 13 can be used as light sources, and hence the deterioration of the freshness of food resulting from heat can be easily suppressed as compared with the case where a fluorescent lamp or the like is used as a light source.

According to the first embodiment, as hereinabove described, the green phosphor 12 is configured to contain one selected from β-sialon or (Ba,Sr)₂SiO₄:Eu. Thus, the green phosphor 12 having the narrow emission spectrum with the half width of not more than 80 nm can be obtained, and hence inclusion of the wavelength component in the vicinity of 600 nm causing a sense of spoilage of food due to light of a green wavelength can be suppressed.

According to the first embodiment, as hereinabove described, the blue LED element 11, the green phosphor 12, and the red LED element 13 are selected such that the light synthesized by the blue LED element 11, the phosphor 12, and the red LED element 13, employed for illumination of meat becomes the white light whose wavelength component in the vicinity of 600 nm is reduced. Thus, inclusion of the wavelength component in the vicinity of 600 nm making fat on meat to appear yellow (causing a sense of spoilage) in the synthesized light can be suppressed, and hence the fat on meat can be made to appear whiter, so that generation of a sense of spoilage of meat by the illumination light of the meat LED lighting device 10 can be suppressed.

According to the first embodiment, as hereinabove described, the blue LED element 11 is configured to have the emission peak wavelength in the range of at least 420 nm to less than 480 nm. Thus, the green phosphor 12 having the emission peak wavelength of not more than 560 nm and the emission spectrum with the half width of not more than 80 nm and the red LED element 13 emitting the red light having the emission peak wavelength of at least 620 nm and less than 680 nm and the emission spectrum with the half width of not more than 40 nm can synthesize the white light whose wavelength component in the vicinity of 600 nm is reduced.

According to the first embodiment, as hereinabove described, the intensity of the wavelength component in the vicinity of 600 nm is not more than 80% of the intensity of the emission peak wavelength of the green phosphor 12. Thus, the intensity of the wavelength component in the vicinity of 600 nm causing a sense of spoilage of food is reliably reduced, and hence the generation of a sense of spoilage of food by the illumination light can be reliably suppressed.

### Second Embodiment

A second embodiment is now described with reference to FIG. 1. In this second embodiment, a red LED element 23 has an emission peak wavelength in the vicinity of 625 nm, unlike the aforementioned first embodiment.

A fresh fish LED lighting device 20 according to the second embodiment of the present invention includes a blue LED element 11, a green phosphor 12, and a red LED element 23 emitting red light having the emission peak wavelength in the vicinity of 625 nm, as shown in FIG. 1. The fresh fish LED lighting device 20 is an example of the “food lighting device” in the present invention.

According to the second embodiment, as the blue LED element 11, a blue LED having an emission peak wavelength in the vicinity of 450 nm is employed.

According to the second embodiment, as the green phosphor 12, β-sialon having an emission peak wavelength in the vicinity of 545 nm and a half width of about 54 nm is employed.

According to the second embodiment, as the red LED element 23, a red LED having the emission peak wavelength in the vicinity of 625 nm and a half width of about 15 nm is employed.

The fresh fish LED lighting device 20 is configured to reduce a wavelength component in the vicinity of 580 nm of the emission spectrum of white light synthesized by the blue LED element 11, the green phosphor 12, and the red LED element 23. Reducing the wavelength component in the vicinity of 580 nm means a state at an intensity relatively lower than the intensity of the emission peak wavelength of the emission spectrum of the green phosphor 12. The intensity of the wavelength component in the vicinity of 580 nm is preferably not more than 80% of the intensity of the emission peak wavelength of the green phosphor 12. The intensity of the wavelength component in the vicinity of 580 nm is more preferably not more than 50% of the intensity of the emission peak wavelength of the green phosphor 12. The intensity of the wavelength component in the vicinity of 580 nm is still more preferably not more than 40% of the intensity of the emission peak wavelength of the green phosphor 12.

The fresh fish LED lighting device 20 is configured such that the color temperature of the white light synthesized by the blue LED element 11, the green phosphor 12, and the red LED element 23 is less than 8000 K.

The remaining structure of the fresh fish LED lighting device 20 according to the second embodiment is similar to that of the meat LED lighting device 10 according to the aforementioned first embodiment.

According to the second embodiment, the following effects can be obtained.

According to the second embodiment, as hereinabove described, the blue LED element 11, the green phosphor 12, and the red LED element 23 are selected such that the light synthesized by the blue LED element 11, the green phosphor 12, and the red LED element 23 becomes the white light whose wavelength component in the vicinity of 580 nm is reduced, whereby a deterioration of the freshness of food (fresh fish) resulting from heat can be suppressed, similarly to the aforementioned first embodiment. Furthermore, inclusion of the wavelength component close to 580 nm and in the vicinity of 600 nm causing a sense of spoilage of food in the synthesized light can be suppressed, and hence generation of a sense of spoilage of food by illumination light of the fresh fish LED lighting device 20 can be suppressed. Consequently, the intrinsic freshness of food can be effectively exhibited, and hence the freshness of food can be emphasized to the consumer, and consumer's motivation for purchase can be promoted.

According to the second embodiment, as hereinabove described, the blue LED element 11 has the emission peak wavelength in the vicinity of 450 nm, the green phosphor 12 is β-sialon having the emission peak wavelength in the vicinity of 545 nm and the half width of 54 nm, and the red LED element 13 has the emission peak wavelength in the vicinity of 625 nm. Thus, the white light whose wavelength component in the vicinity of 580 nm is reduced can be easily synthesized.

According to the second embodiment, as hereinabove described, the intensity of the wavelength component in the vicinity of 580 nm is not more than 80% of the intensity of the emission peak wavelength of the green phosphor 12. Thus, the intensity of the wavelength component in the vicinity of 580 nm causing a sense of spoilage of food is reliably reduced, and hence the generation of a sense of spoilage of food by the illumination light can be reliably suppressed.

According to the second embodiment, as hereinabove described, the blue LED element 11, the green phosphor 12, and the red LED element 23 are selected such that the light synthesized by the blue LED element 11, the phosphor 12, and the red LED element 23, employed for illumination of fresh fish becomes the white light whose wavelength component in the vicinity of 580 nm is reduced. According to this structure, the red LED element 23 having the emission peak wavelength on the shorter wavelength side (in the vicinity of 620 nm) can be easily employed. Consequently, the luminous efficiency of the red LED element 23 can be improved as compared with the case where the red LED element 13 is employed, and hence the power consumption of the fresh fish LED lighting device 20 can be reduced.

The remaining effects of the second embodiment are similar to those of the aforementioned first embodiment.

### Third Embodiment

A third embodiment is now described with reference to FIG. 2. In this third embodiment, white light is synthesized by a blue LED element 11, a green phosphor 12 (shown by hatching), and a red phosphor 34 (shown by hatching), unlike each of the aforementioned first and second embodiments in which the white light is synthesized by the blue LED element 11, the green phosphor 12, and the red LED element 13 (23).

A meat LED lighting device 30 according to a third embodiment of the present invention includes the blue LED device 11, the green phosphor 12, and the red phosphor 34 absorbing light of a blue wavelength and emitting red light, as shown in FIG. 2. The meat LED lighting device 30 is an example of the “food lighting device” in the present invention.

According to the third embodiment, the red phosphor 34 is dispersed in a sealing resin 16, similarly to the green phosphor 12. In the red phosphor 34, light excited by blue light has an emission peak wavelength of at least 620 nm and less than 680 nm and an emission spectrum with a half width of not more than 40 nm. Specifically, the red phosphor 34 is formed of a complex fluoride phosphor obtained by adding Mn to A₂MF₆ (A represents Na, K, Rb, or the like, and M represents Si, Ge, Ti, or the like).

The remaining structure of the meat LED lighting device 30 according to the third embodiment is similar to that of the meat LED lighting device 10 according to the aforementioned first embodiment.

According to the third embodiment, the following effects can be obtained.

According to the third embodiment, as hereinabove described, the red phosphor 34 in which the light excited by the blue light emitted from the blue LED element 11 has the emission peak wavelength of at least 620 nm and less than 680 nm and the emission spectrum with the half width of not more than 40 nm is employed. According to this structure, the blue LED element 11 can be used as a light source, and hence a deterioration of the freshness of food resulting from heat can be easily suppressed, as compared with the case where a fluorescent lamp or the like is used as a light source.

According to the third embodiment, as hereinabove described, a dam material 15 provided to surround the blue LED element 11 and the transparent sealing resin 16 configured to seal the blue LED element 11 are provided. Furthermore, the green phosphor 12 and the red phosphor 34 are dispersed in the sealing resin 16 sealing the blue LED element 11. Thus, white light can be synthesized while the number of LED elements (one blue LED element 11) is reduced.

According to the third embodiment, as hereinabove described, the green phosphor 12 and the red phosphor 34 are dispersed in the single sealing resin 16. Thus, the structure of the meat LED lighting device 30 can be simplified, unlike the case where the green phosphor 12 and the red phosphor 34 are dispersed in separate sealing resins 16.

According to the third embodiment, as hereinabove described, the red phosphor 34 is formed of the complex fluoride phosphor. According to this structure, the red phosphor 34 having the emission spectrum with the half width of not more than 40 nm can be obtained, and hence inclusion of a wavelength component in the vicinity of 600 nm causing a sense of spoilage of food due to light of a red wavelength can be suppressed.

The remaining effects of the third embodiment are similar to those of the aforementioned first embodiment.

Examples (Example 1 and Example 2) of actually preparing lighting devices corresponding to the aforementioned first and second embodiments are now described.

### Example 1

A meat lighting device in Example 1 was constituted by a blue LED element having an emission peak wavelength in the vicinity of 450 nm, a green phosphor made of β-sialon having an emission peak wavelength in the vicinity of 545 nm and a half width of about 54 nm, and a red LED element having an emission peak wavelength in the vicinity of 660 nm and a half width of about 15 nm. The blue LED element having an output of 20 mW was employed, and the red LED element having an output of 30 mW was employed. The β-sialon was mixed (dispersed) in a sealing resin such that the ratio by weight of the β-sialon was 12% by weight with respect to the total weight of the sealing resin and the β-sialon.

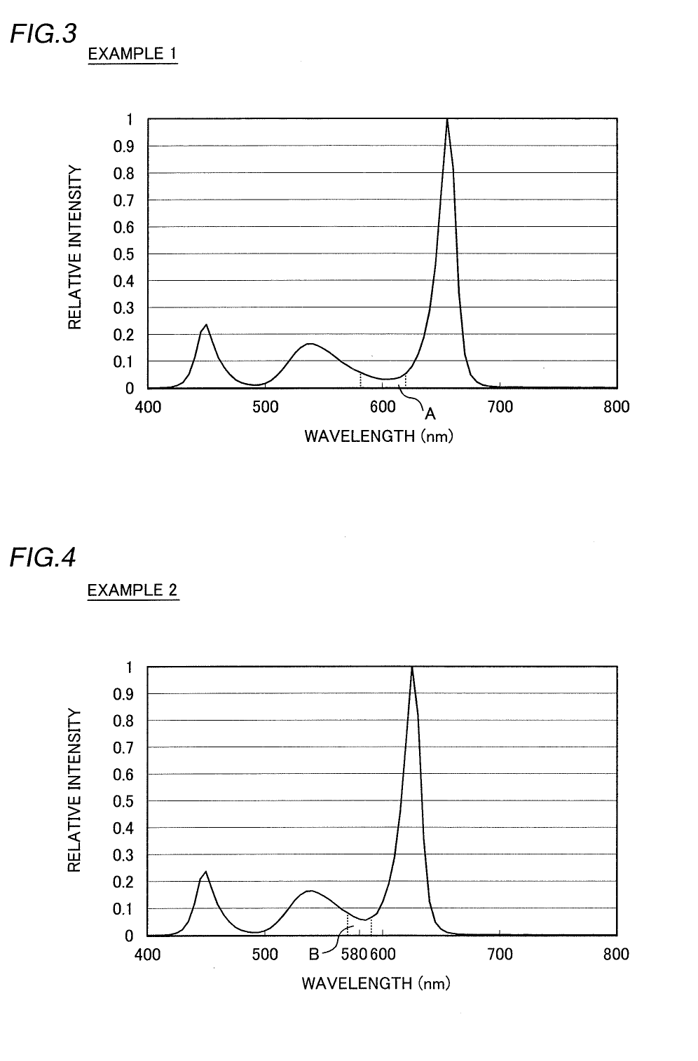

When the meat lighting device constituted by the aforementioned components in Example 1 was allowed to emit light by voltage application thereto, an emission spectrum shown in FIG. 3 was obtained. The obtained color temperature of light was about 5000 K. The emission spectrum and the color temperature were measured by a spectrometer. As shown in FIG. 3, the half width of each phosphor was narrow, and hence the emission spectrum obtained by the meat lighting device in Example 1 was not formed in the form of a smooth mountain obtained by connecting wavelength components of colors but was formed in the form of a mountain having three distinct peaks of blue light (emission peak wavelength of 450 nm), green light (emission peak wavelength of 545 nm), and red light (emission peak wavelength of 660 nm) and valleys of the peaks in the vicinity of 490 nm and 600 nm (range A).

In the obtained emission spectrum, the intensity of the wavelength component in the vicinity of 600 nm was relatively limited as compared with that of green light having an emission peak wavelength of 545 nm. Specifically, the intensity of the wavelength component in the range A of at least about 580 nm to not more than about 620 nm was not more than 50% of the intensity of the emission peak wavelength of 545 nm of the green light. Furthermore, the intensity of the wavelength component of 600 nm was not more than 20% of the intensity of the emission peak wavelength of 545 nm of the green light. It has been confirmed from the above that light whose wavelength component in the vicinity of 600 nm is reduced is obtained with the aforementioned structure of the meat lighting device in Example 1.

### Example 2

A fresh fish lighting device in Example 2 was constituted by a blue LED element having an emission peak wavelength in the vicinity of 450 nm, a green phosphor made of β-sialon having an emission peak wavelength in the vicinity of 545 nm and a half width of about 54 nm, and a red LED element having an emission peak wavelength in the vicinity of 625 nm and a half width of about 15 nm. The blue LED element having an output of 20 mW was employed, and the red LED element having an output of 30 mW was employed. The β-sialon was mixed (dispersed) in a sealing resin such that the ratio by weight of the β-sialon was 12% by weight with respect to the total weight of the sealing resin and the β-sialon.

When the fresh fish lighting device constituted by the aforementioned components in Example 2 was allowed to emit light by voltage application thereto, an emission spectrum shown in FIG. 4 was obtained. The obtained color temperature of light was about 5000 K. The emission spectrum and the color temperature were measured by a spectrometer. As shown in FIG. 4, the emission spectrum obtained by the fresh fish lighting device in Example 2 was formed with a mountain having three distinct peaks of blue light (emission peak wavelength of 450 nm), green light (emission peak wavelength of 545 nm), and red light (emission peak wavelength of 625 nm) and valleys of the peaks in the vicinity of 490 nm and 580 nm (range B).

In the emission spectrum obtained by the fresh fish lighting device in Example 2, the intensity of the wavelength component in the vicinity of 580 nm was relatively limited as compared with that of green light having an emission peak wavelength of 545 nm. Specifically, the intensity of the wavelength component in the range B of at least about 570 nm to not more than about 590 nm was not more than 50% of the intensity of the emission peak wavelength of 545 nm of the green light. Furthermore, the intensity of the wavelength component of 580 nm was not more than 40% of the intensity of the emission peak wavelength of 545 nm of the green light. It has been confirmed from the above that light whose wavelength component in the vicinity of 580 nm is reduced is obtained with the aforementioned structure of the fresh fish lighting device in Example 2, similarly to in Example 1.

### Comparative Example

As a comparative example, an emission spectrum in a common LED lighting device having a color temperature of 5000 K was shown in FIG. 5. As shown in FIG. 5, the LED lighting device in the comparative example had the emission spectrum in the form of a smooth mountain over the wavelength range of about 500 nm to about 650 nm. This is because a phosphor having a wide half width is employed for light emission. In the LED lighting device in this comparative example, light whose wavelength component in the vicinity of 580 nm or in the vicinity of 600 nm is reduced could not be obtained.

The embodiments and Examples disclosed this time must be considered as illustrative in all points and not restrictive. The range of the present invention is shown not by the above description of the embodiments and Examples but by the scope of claims for patent, and all modifications within the meaning and range equivalent to the scope of claims for patent are further included.

For example, while the green phosphor 12 and/or the red phosphor 34 are dispersed in the sealing resin 16 in each of the aforementioned first to third embodiments, the present invention is not restricted to this. According to the present invention, any structure may alternatively be employed so far as the light of the blue LED element 11 can be emitted to the green phosphor 12 and/or the red phosphor 34. For example, the green phosphor and/or the red phosphor may be layered on a surface of the sealing resin 16.

While the green phosphor 12 is made of one or a combination of two selected from β-sialon or (Ba,Sr)₂SiO₄:Eu in each of the aforementioned first to third embodiments, the present invention is not restricted to this. According to the present invention, a green phosphor made of a material other than the above may alternatively be employed so far as the same has an emission peak wavelength of not more than 560 nm and an emission spectrum with a half width of not more than 80 nm.

While the red phosphor 34 is made of the complex fluoride phosphor in the aforementioned third embodiment, the present invention is not restricted to this. According to the present invention, a red phosphor made of a material other than the complex fluoride phosphor may alternatively be employed so far as the same has an emission peak wavelength of at least 620 nm and less than 680 nm and an emission spectrum with a half width of not more than 40 nm.

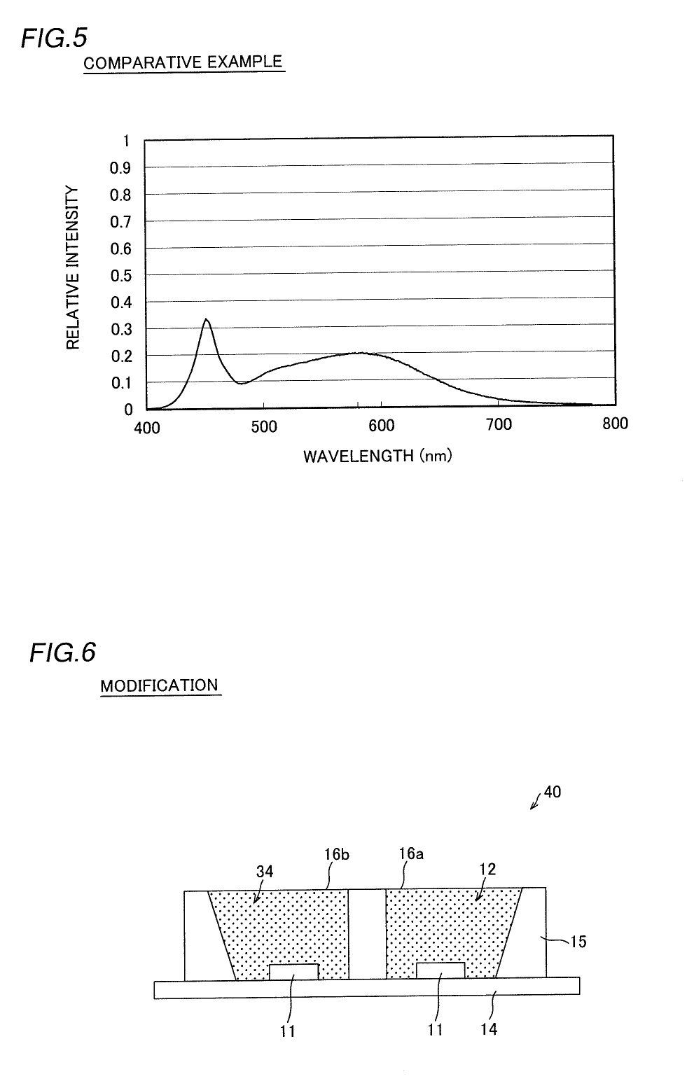

While the green phosphor 12 and the red phosphor 34 are dispersed in the single sealing resin 16 in the aforementioned third embodiment, the present invention is not restricted to this. According to the present invention, a sealing resin 16a in which a green phosphor 12 (shown by hatching) is dispersed and a sealing resin 16b in which a red phosphor 34 (shown by hatching) is dispersed may alternatively be formed separately as in a meat LED lighting device 40 according to a modification shown in FIG. 6. In this case, blue LED elements 11 configured to emit excitation light are provided separately for the green phosphor 12 and the red phosphor 34. Thus, adjustment of the amount of dispersion of the green phosphor 12 and adjustment of the amount of dispersion of the red phosphor 34 can be performed separately.

While the intensity of the wavelength component in the vicinity of 580 nm or in the vicinity of 600 nm was not more than 50% of the intensity of the emission peak wavelength of the green light in each of the aforementioned Examples 1 and 2, the present invention is not restricted to this. According to the present invention, it is only required to render at least the intensity of the wavelength component in the vicinity of 580 nm or in the vicinity of 600 nm relatively lower than the emission peak intensity of green light. Therefore, the meat LED lighting device 10 or 30 according to the first or third embodiment of the present invention may alternatively be employed as a fresh fish lighting device, or the fresh fish LED lighting device 20 according to the second embodiment of the present invention may alternatively be employed as a meat lighting device.

While the food lighting device according to the present invention is applied to the meat or fresh fish lighting device in each of the aforementioned first to third embodiments, the present invention is not restricted to this. According to the present invention, the food lighting device is applicable to various food lighting devices by selecting a red LED element or a red phosphor having an emission peak wavelength optimum for a target of illumination.

Furthermore, the present invention is applicable to lighting devices of various forms such as straight tube, curved, circular, and bulb type light devices.

What is claimed is:

1. A food lighting device comprising:
a blue LED element emitting light having a blue wavelength;
a green phosphor having an emission peak wavelength of not more than 560 nm and an emission spectrum with a half width of not more than 80 nm; and
a red LED element or a red phosphor emitting red light having an emission peak wavelength of at least 620 nm and less than 680 nm and an emission spectrum with a half width of not more than 40 nm, wherein
the blue LED element, the green phosphor, and the red LED element or the red phosphor are selected such that light synthesized by the blue LED element, the green phosphor, and the red LED element or the red phosphor becomes white light whose wavelength component in a vicinity of 580 nm or in a vicinity of 600 nm is reduced.

2. The food lighting device according to claim 1, wherein
an emission spectrum of the light synthesized by the blue LED element, the green phosphor, and the red LED element or the red phosphor is configured such that an intensity of the wavelength component in the vicinity of 580 nm or in the vicinity of 600 nm is relatively small as compared with an intensity of the emission peak wavelength of the green phosphor.

3. The food lighting device according to claim 1, wherein
the red light having the emission peak wavelength of at least 620 nm and less than 680 nm and the emission spectrum with the half width of not more than 40 nm is emitted by the red LED element, and
the blue LED element, the green phosphor, and the red LED element are selected such that light synthesized by the blue LED element, the green phosphor, and the red LED element becomes the white light whose wavelength component in the vicinity of 580 nm or in the vicinity of 600 nm is reduced.

4. The food lighting device according to claim 3, further comprising a dam material provided to surround the blue LED element and the red LED element and transparent sealing resins configured to seal the blue LED element and the red LED element, wherein
the green phosphor is dispersed in the transparent sealing resin sealing the blue LED element.

5. The food lighting device according to claim 4, wherein
the transparent sealing resin configured to seal the red LED element is provided separately from the transparent sealing resin sealing the blue LED element, in which the green phosphor is dispersed.

6. The food lighting device according to claim 1, wherein
a color temperature of the light synthesized by the blue LED element, the green phosphor, and the red LED element or the red phosphor is less than 8000 K.

7. The food lighting device according to claim 6, wherein
the color temperature of the light synthesized by the blue LED element, the green phosphor, and the red LED element or the red phosphor is less than 7000 K.

8. The food lighting device according to claim 1, wherein
in the green phosphor, light excited by blue light emitted from the blue LED element has an emission peak wavelength of not more than 560 nm and an emission spectrum with a half width of not more than 80 nm, and
in the red phosphor, the light excited by the blue light emitted from the blue LED element has an emission peak wavelength of at least 620 nm and less than 680 nm and an emission spectrum with a half width of not more than 40 nm.

9. The food lighting device according to claim 8, further comprising a dam material provided to surround the blue LED element and a transparent sealing resin configured to seal the blue LED element, wherein
the green phosphor and the red phosphor are dispersed in the transparent sealing resin sealing the blue LED element.

10. The food lighting device according to claim 9, wherein
the green phosphor and the red phosphor are dispersed in the transparent sealing resin that is single.

11. The food lighting device according to claim 9, wherein
the transparent sealing resin comprises a sealing resin in which the green phosphor is dispersed and a sealing resin provided separately from the sealing resin in which the green phosphor is dispersed, in which the red phosphor is dispersed.

12. The food lighting device according to claim 1, wherein
the green phosphor comprises one selected from β-sialon or (Ba,Sr)₂SiO₄:Eu.

13. The food lighting device according to claim 1, wherein
the red phosphor comprises a complex fluoride phosphor.

14. The food lighting device according to claim 1, wherein
the food lighting device is employed for illumination of meat, and
the blue LED element, the green phosphor, and the red LED element or the red phosphor are selected such that the light synthesized by the blue LED element, the green phosphor, and the red LED element or the red phosphor becomes white light whose wavelength component in the vicinity of 600 nm is reduced.

15. The food lighting device according to claim 14, wherein
the blue LED element has an emission peak wavelength in a range of at least 420 nm to less than 480 nm.

16. The food lighting device according to claim 14, wherein
an intensity of the wavelength component in the vicinity of 600 nm is not more than 80% of an intensity of the emission peak wavelength of the green phosphor.

17. The food lighting device according to claim 1, employed for illumination of fresh fish, wherein
the blue LED element, the green phosphor, and the red LED element or the red phosphor are selected such that the light synthesized by the blue LED element, the green phosphor, the red LED element or the red phosphor becomes white light whose wavelength component in the vicinity of 580 nm is reduced.

18. The food lighting device according to claim 17, wherein
the blue LED element has an emission peak wavelength in a vicinity of 450 nm, the green phosphor comprises β-sialon having an emission peak wavelength in a vicinity of 545 nm and a half width of 54 nm, and the red LED element has an emission peak wavelength in a vicinity of 625 nm.

19. The food lighting device according to claim 17, wherein
an intensity of the wavelength component in the vicinity of 580 nm is not more than 80% of an intensity of the emission peak wavelength of the green phosphor.

20. A meat lighting device comprising:
a blue LED element emitting light having a blue wavelength;
a green phosphor having an emission peak wavelength of not more than 560 nm and an emission spectrum with a half width of not more than 80 nm; and
a red LED element or a red phosphor emitting red light having an emission peak wavelength of at least 620 nm and less than 680 nm and an emission spectrum with a half width of not more than 40 nm, wherein
the blue LED element, the green phosphor, and the red LED element or the red phosphor are selected such that light synthesized by the blue LED element, the green phosphor, and the red LED element or the red phosphor becomes white light whose wavelength component in a vicinity of 600 nm is reduced.
